(19) United States
(12) Patent Application Publication
(10) Pub. No.: US 2007/0045647 A1
(43) Pub. Date: Mar. 1, 2007

(54) Display panel package

(75) Inventors: Yi-Chin Lin, Taichung City (TW); Hen-Ta Kang, Taichung City (TW); Kun-Chang Ho, Taichung County (TW); Lin Lin, Taichung (TW)

Correspondence Address: BACON & THOMAS, PLLC, 625 SLATERS LANE, FOURTH FLOOR, ALEXANDRIA, VA, 22314, US

(73) Assignee: Wintek Corporation, TAICHUNG (TW)

(21) Appl. No.: 11/216,047

(22) Filed: Sep. 1, 2005

(51) Int. Cl. H01L 33/00

(52) U.S. Cl. 257/99

(57) ABSTRACT

A display panel package includes a first electronic member, a second electronic member and an electrically conductive structure for electrically connecting the first electronic member and the second electronic member. The electrically conductive structure has a plurality of bumps electrically and spacedly connected to the first electronic member, and a plurality of posts electrically connected to the second electronic member and penetrated into the bumps respectively.

### BACKGROUND OF THE INVENTION

1. Field of the Invention

The present invention relates generally to a package of a display panel, and more particularly to a display panel package having two electronic members electrically connected with each other by a penetration method.

2. Description of the Related Art

FIG. 1 is a schematic drawing showing a conventional liquid crystal display panel, which comprises a driving integrated circuit (driving IC) board 1, a conductive panel 2, and an anisotropic conductive film 3 sandwiched between the driving IC board 1 and the conductive panel 2 for electrically connecting the driving IC board 1 and the conductive panel 2. The driving IC board 1 has an aluminum (Al) layer 1a on which a plurality of gold bumps 1b are formed as I/Os of the driving IC board 1. Under the limitation of the present manufacturing process, a minimum width a (so called the width) of the gold bumps 1b is about 20 μm and a minimum interval (so called the space) between two adjacent gold bumps 1b is about 10 μm.

The conductive panel 2 includes a substrate 2a, indium tin oxide (ITO) electrodes 2b and chromium (Cr) layers 2c on the ITO electrodes 2b respectively. The ITO electrodes 2b are spacedly respectively formed on the substrate 2a and the Cr layers 2c are correspondingly respectively formed on the ITO electrodes 2b.

The anisotropic conductive film 3 has an adhesive layer 3a with conductive particles 3b therein. The adhesive layer 3a bonds the driving IC board 1 on the conductive panel 2, and the conductive particles 3b are in touch with the gold bumps 1b and the corresponding Cr layers 2c respectively to electrically connecting the driving IC board 1 and the conductive panel 2, that is, the conductive particles 3b serve as electrically conductive bridges between the conductive panel 2 and the driving IC board 1.

The anisotropic conductive films 3 are broadly incorporated in electrical connection of the driving IC board 1 and the conductive panel 2. However, as shown in FIG. 1, the conductive particles 3b are distributed not only under the gold bumps 1b and above the Cr layers 2c but also between the neighborhood gold bumps 1b and the neighborhood Cr layers 2c. In practice, the sizes of the conductive particles 3b are about 3-5 μm. While there are two or more conductive particles 3b fallen in between the two neighborhood gold bumps 1b, which interval is about 10 μm, and the particles 3b are in tough with each other, the bumps 1b are electrically conducted to each other via the conductive particles 3b; therefore, a short-circuit between the neighborhood bumps 1b occurs. When the driving ICs are designed as fine as possible, such problem is getting worse.

### SUMMARY OF THE INVENTION

The primary objective of the present invention is to provide a display panel package, which prevents a short-circuit between two electronic members.

According to the objective of the present invention, a display panel package comprises a first electronic member, a second electronic member and an electrically conductive structure for electrically connecting the first electronic member and the second electronic member. The electrically conductive structure comprises a plurality of bumps electrically and spacedly connected to the first electronic member, and a plurality of posts electrically connected to the second electronic member and penetrated into the bumps respectively.

### BRIEF DESCRIPTION OF THE DRAWINGS

FIG. 1 is a schematic sectional view of the conventional liquid crystal display panel package, showing the driving IC board and the conductive panel in electrical connection by the anisotropic conductive film;

FIG. 2 is a schematic sectional view of the first and second electronic members of a preferred embodiment of the present invention;

FIG. 3 is an exploded schematic view of the preferred embodiment of the present invention, showing a non-conductive film is set between the first and second electronic members for bonding;

FIG. 4 is a schematic drawing of the preferred embodiment of the present invention, showing the first and second electronic members electrically connected with each other by penetration;

FIG. 5 is a schematic drawing of the preferred embodiment of the present invention, showing a UV adhesion is injected for bonding the first and second electronic members together;

FIG. 6 is a schematic drawing of the preferred embodiment of the present invention, showing the UV adhesion is cured by the exposure of light;

FIGS. 7A-7E are schematic drawings of the present invention, showing the procedures of making the second conductive layer;

FIGS. 8A-8E are schematic drawings of the present invention, showing the procedures of making microscale posts;

FIGS. 9A-9D are schematic drawings of the present invention, showing the procedures of making nanoscale posts according to a preferred embodiment of the present invention;

FIGS. 10A-10H are schematic drawings of the present invention, showing the procedures of making nanoscale posts according to another preferred embodiment of the present invention;

FIGS. 11A-11F are schematic drawings of the present invention, showing the procedures of making nanoscale posts according to still another preferred embodiment of the present invention, and

FIG. 12 is a schematic drawing of the present invention, showing the posts formed on the conductive film directly.

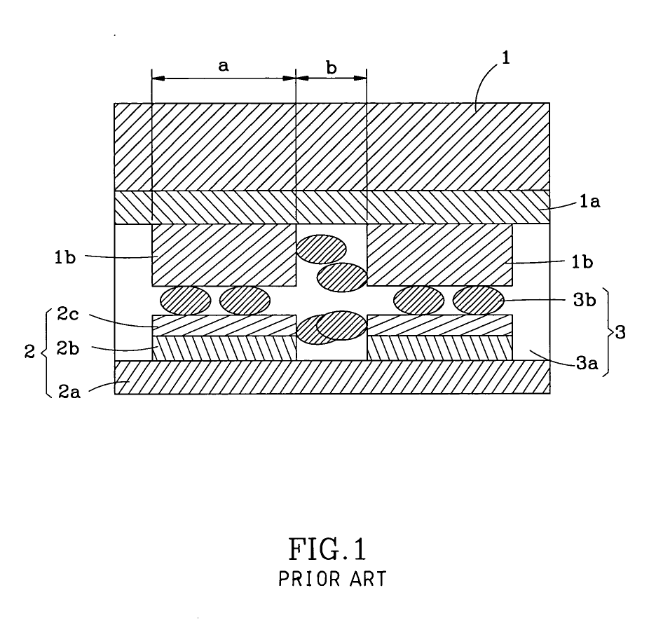

### DETAILED DESCRIPTION OF THE INVENTION

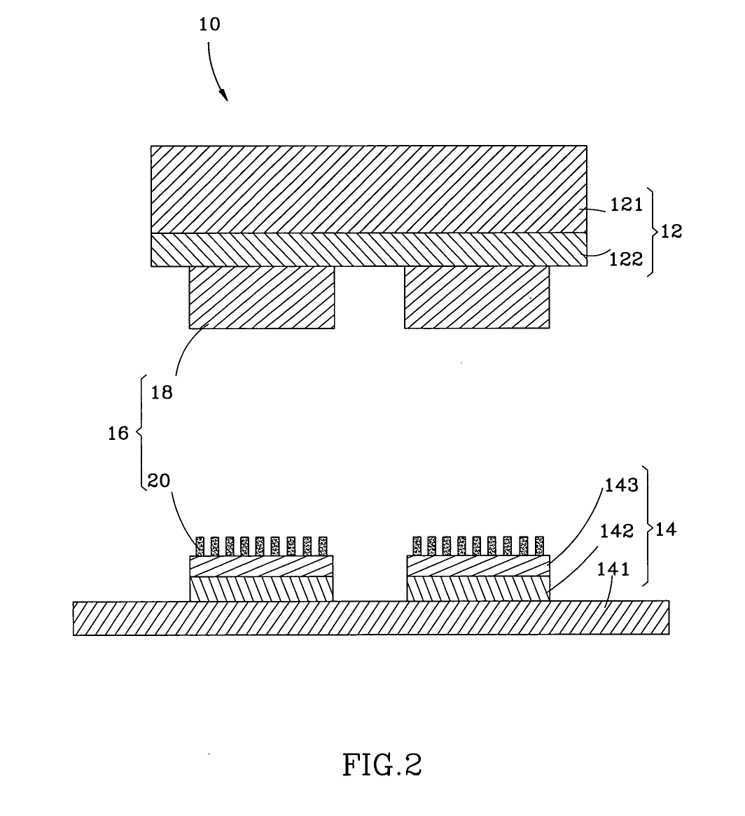

As shown in FIG. 2, a display panel package 10, for example a liquid crystal display panel package, of the preferred embodiment of the present invention mainly comprises a first electronic member 12, a second electronic member 14 and an electrically conductive structure 16 for electrically connecting the first and second electronic members 12 and 14.

The first electronic member 12 includes a driving integrated circuit (IC) board 121 and a first conductive layer 122. The first conductive layer 122 is made of aluminum with a side electrically connected to the driving IC board 121.

The second electronic member 14 includes a substrate 141, a plurality of conductive films 142 and a plurality of second conductive layers 143. The conductive films 142 are made of indium tin oxide (ITO) formed on the substrate 141. The second conductive layers 143 are formed on the conductive films 142 respectively. In the preferred embodiment, the second conductive layers 143 are made of chromium (Cr). The method of making the second conductive layers 143 will be described hereinafter.

The electrically conductive structure 16 includes a plurality of bumps 18 and posts 20. The bumps 18, which are made of electrically conductive materials such as gold or aluminum, are spacedly formed on an opposite side of the first conductive layer 122. The bumps 18 are made by the photolithography-etching method, and the bumps 18 are already pre-formed on the first electronic member 12 before assembling the display panel package.

The sizes of the posts 20 can be microscale or nanoscale according to the manufacturing processes. In the present preferred embodiment, the posts 20 are microscale posts with ends electrically connected to the second conductive layers 143 respectively and opposite ends pointing upright and toward the bumps 18 of the first electronic member 12, as shown in FIG. 2. The posts 20 are also made of a conductive material, such as nickel, cobalt, and wolfram, having a hardness greater than that of the bumps 18. The methods of making the posts 20 will be described hereinafter too.

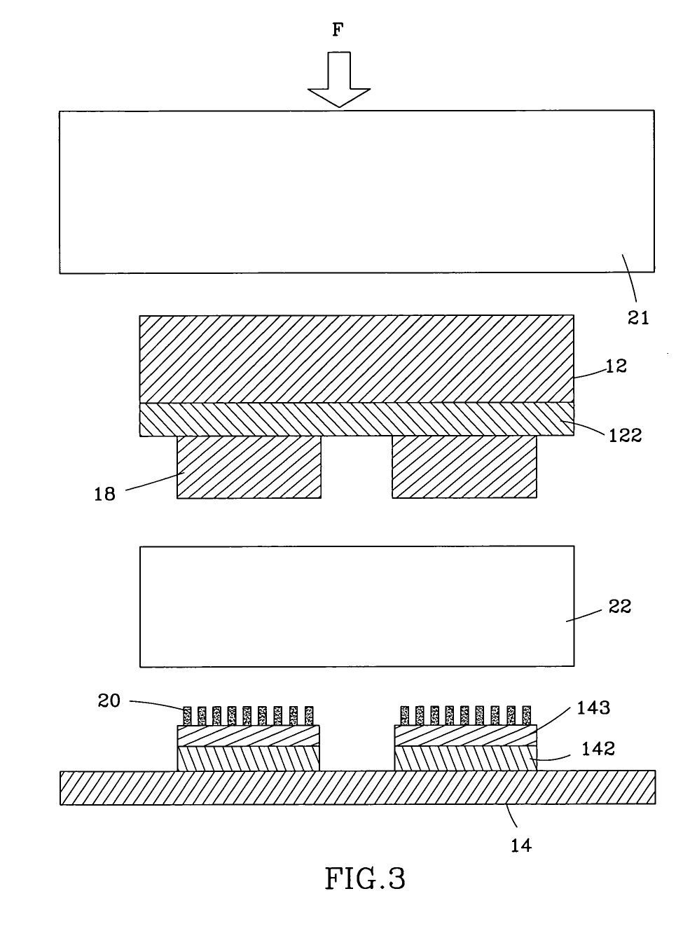

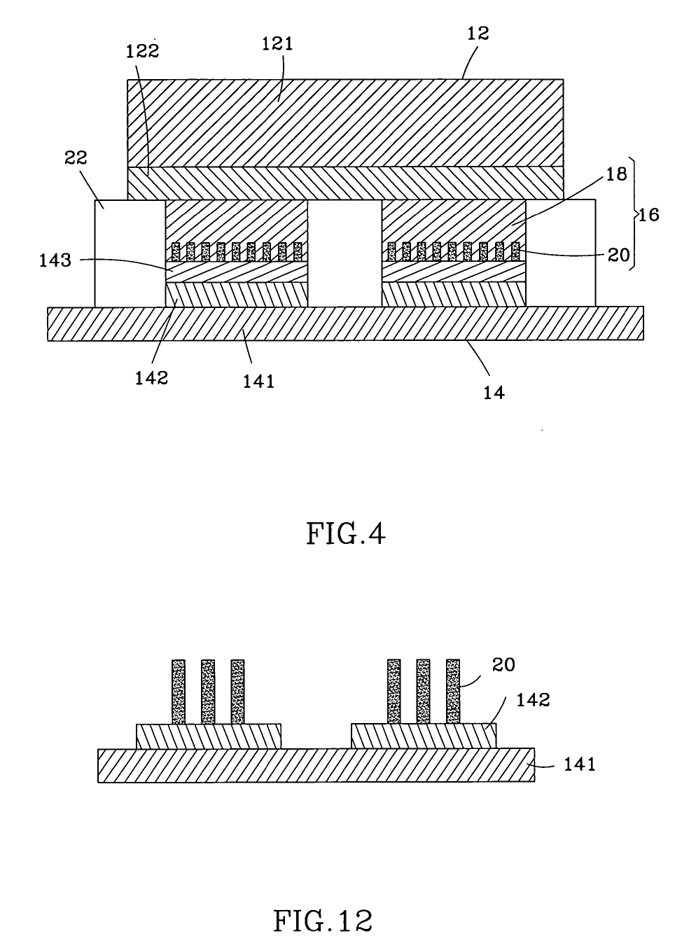

As shown in FIG. 3 and FIG. 4, when assembling, a non-conductive film (NCF) 22 is provided between the first and second electronic members 12 and 14, the bumps 18 face the posts 20, and the second electronic member 14 is fixed in a stationary position. A hot press device 21 exerts a force F on the first electronic member 12 to move the first electronic member 12 toward the second electronic member 14. When the first electronic member 12 contacts the second electronic member 14, the posts 20 will penetrate into the bumps 18 respectively because the posts 20 are harder than the bumps 18. The force F is stopped when the bumps 18 touch the second conductive layers 143. And then, the NCF 22 is heated for curing to bond the first and second electronic members 12 and 14. Under this circumstance, the first and second electronic members 12 and 14 are electrically connected, and the package process is completed.

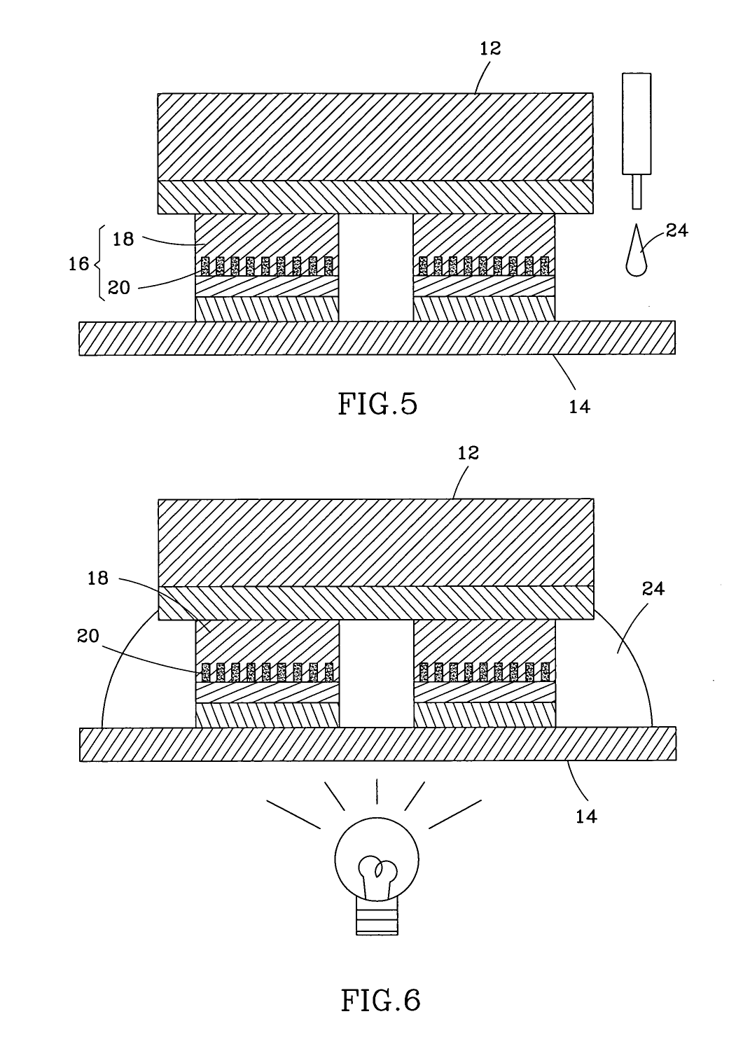

As shown in FIG. 5 and FIG. 6, a method of assembling the first and second electronic members 12 and 14 includes the steps of moving the first electronic member 12 toward the second electronic member 14 to make the posts 20 piercing into the bumps 18 respectively, then providing a non-conductive UV adhesion 24 between the first and second electronic members 12 and 14 to cover the bumps 18 and the posts 20, and then curing the UV adhesion 24 by the exposure of light for bonding and packaging the first and second electronic members 12 and 14 together.

The way of electrically connecting two fine electronic members is done by penetration of the posts 20 into the bumps 18 in stead of the use of the anisotropic conductive film, thereby preventing a short-circuit due to the use of the anisotropic conductive film. In addition, the present invention is incorporated with the non-conductive film 22 or the UV adhesion 24 for package, which are much cheaper than the conventional anisotropic conductive film. It reduces the cost of manufacture.

A method of making the second conductive layers 143 is described hereunder:

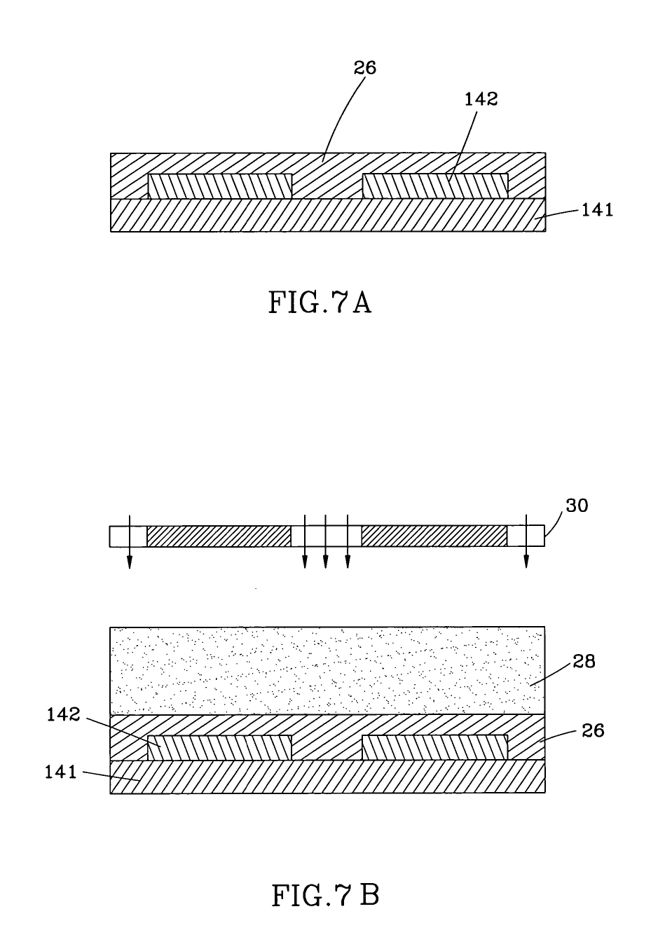

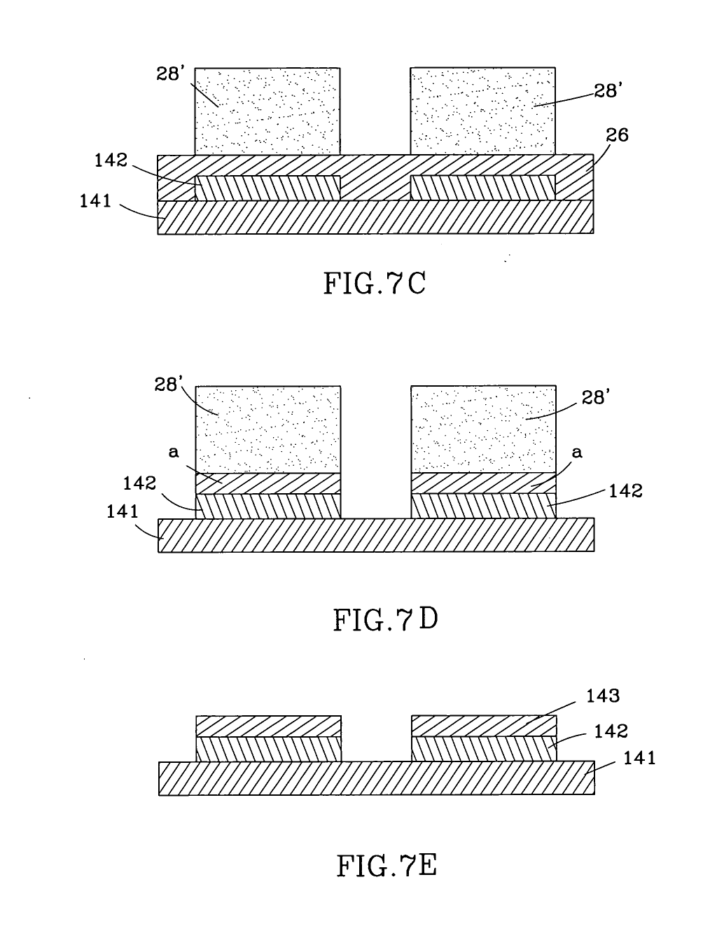

As shown in FIG. 7A, a chromium (Cr) metal film 26 is provided on the substrate 141 to cover all of the conductive films 142. As shown in FIG. 7B, a photoresist 28, which is a positive photoresist in the present embodiment, is then coated on the Cr metal film 26 for the exposure treatment. And then, a mask 30 is provided on the photoresist 28 to expose a predetermined portion of the photoresist 28. As shown in FIG. 7C, the substrate 141 is washed by a development solution to removed the exposed portion of the photoresist 28, so that a photoresist 28′ having a predetermined pattern is left and a predetermined portion of the Cr metal layer 26 is exposed. And then, an etching treatment is taken to remove the exposed portion of the Cr metal layer 26 such that a metal pattern a under the photoresist 28′ is left as shown in FIG. 7D. The metal pattern a forms eventually the second conductive layers 143. Finally, the photoresist 28′ is removed to expose the second conductive layers 143 as shown in FIG. 7E, that is, the second conductive layers 143 are correspondingly respectively disposed on the conductive films 142. The method of removing the photoresist includes wet-etching and dry-etching methods, which are well-known in the art so that no further description thereof is necessary to be presented here.

A method of making the microscale posts 20 is described hereunder:

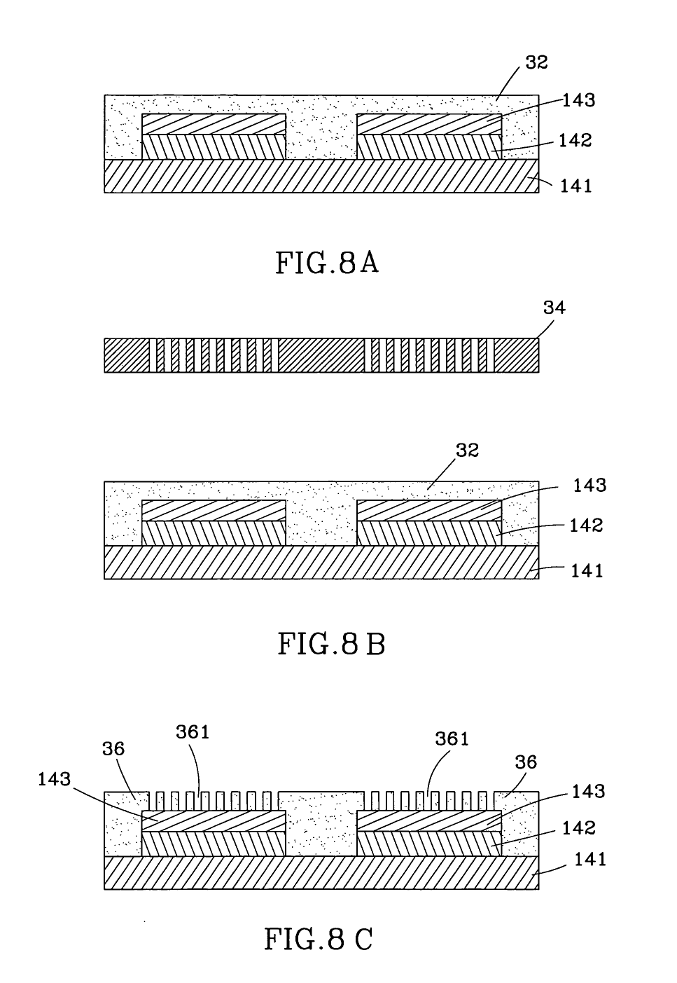

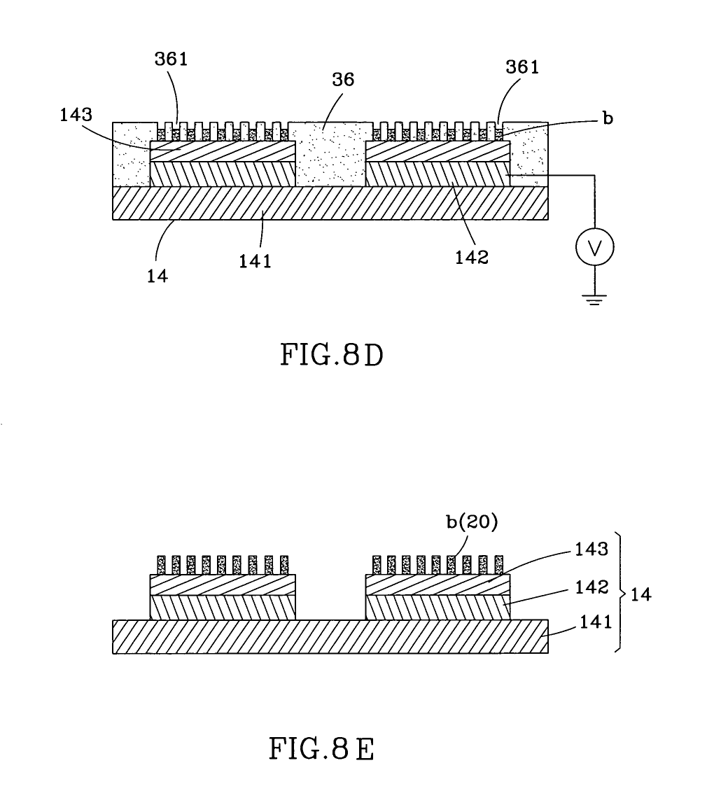

After making the second conductive layers 143, as shown in FIG. 8A, a photoresist 32, e.g. a negative photoresist, is coated on the second electronic member 14 to cover all of the second conductive layers 143. And then, as shown in FIG. 8B, a mask 34 is placed on the photoresist 32 for the exposure treatment. The unexposed portion of the photoresist 32 is removed by the development solution so that a photoresist layer 36, which has a plurality of vias 361 corresponding respectively in location to the second conductive layers 143, is left on the second electronic member 14 as shown in FIG. 8C.

After that, the second electronic member 14 having the photoresist layer 36 is placed into an electroforming tank (not shown), as shown in FIG. 8D, and a voltage is provided on the conductive films 142 to deposit metal depositions b in the vias 361. This process is so-called the electroforming process. Finally, the photoresist layer 36 is removed to have the metal depositions b form the microscale posts 20 on the second electronic member 14.

Methods of making nanoscale posts are described hereunder. The second electronic member 14 used in the methods of making nanoscale posts includes also the substrate 141, the conductive films 142 and the second conductive layers 143. The method of making the second conductive layers 143 is as same as the method described above.

The first method of making the nanoscale posts includes the steps as follows.

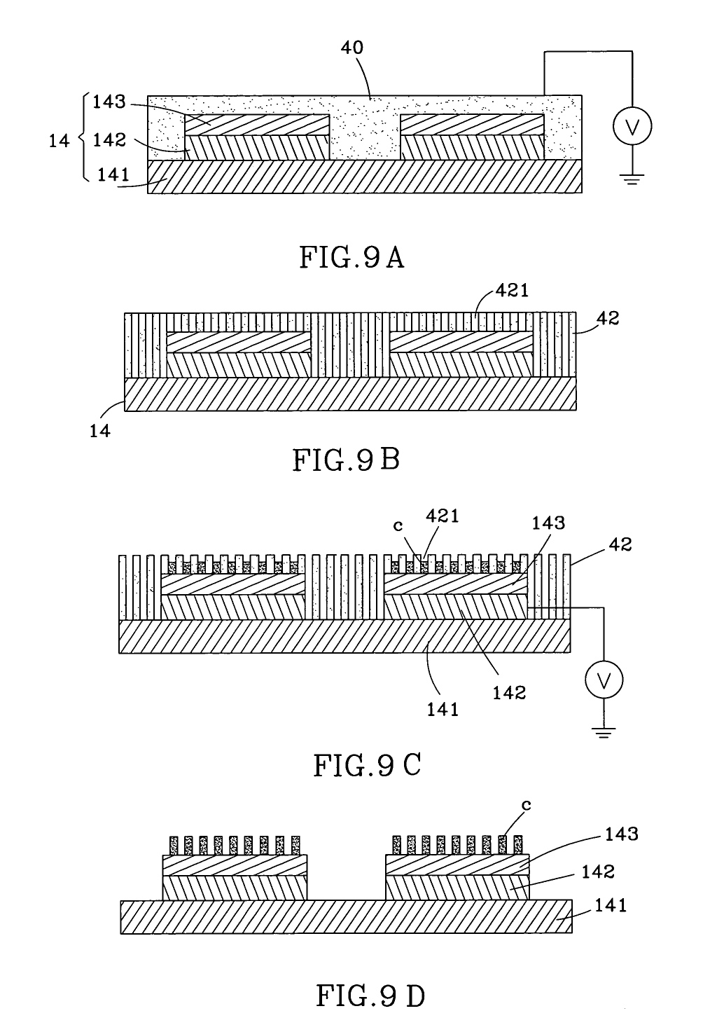

As shown in FIG. 9A, the second electronic member 14 with an aluminum film 40 pre-formed on the second electronic member 14 is placed in an electrolytic bath (not shown). The method of forming the aluminum film 40 on the second electronic member 14 includes sputtering coating, chemical vapor deposition (CVP), or physical vapor deposition (PVD). A positive voltage is applied to the aluminum film 40 and a negative voltage is applied to a graphite electrode (not shown). The aluminum film 40 is therefore oxidized to form an aluminum oxide (Al₂O₃) film 42 having a plurality of nanoscale vias 421 therein, as shown in FIG. 9B. And then, the second electronic member 14 is placed to an electroforming tank (not shown) and provided with a voltage to the conductive film 142, as shown in FIG. 9C, so as to deposit metal depositions c in the vias 421 respectively. And then, the aluminum oxide film 42 is removed by the wet-etching treatment, so that the metal depositions c are left on the second conductive layers 143 to be the nanoscale posts.

The second method of making the nanoscale posts includes the steps hereunder:

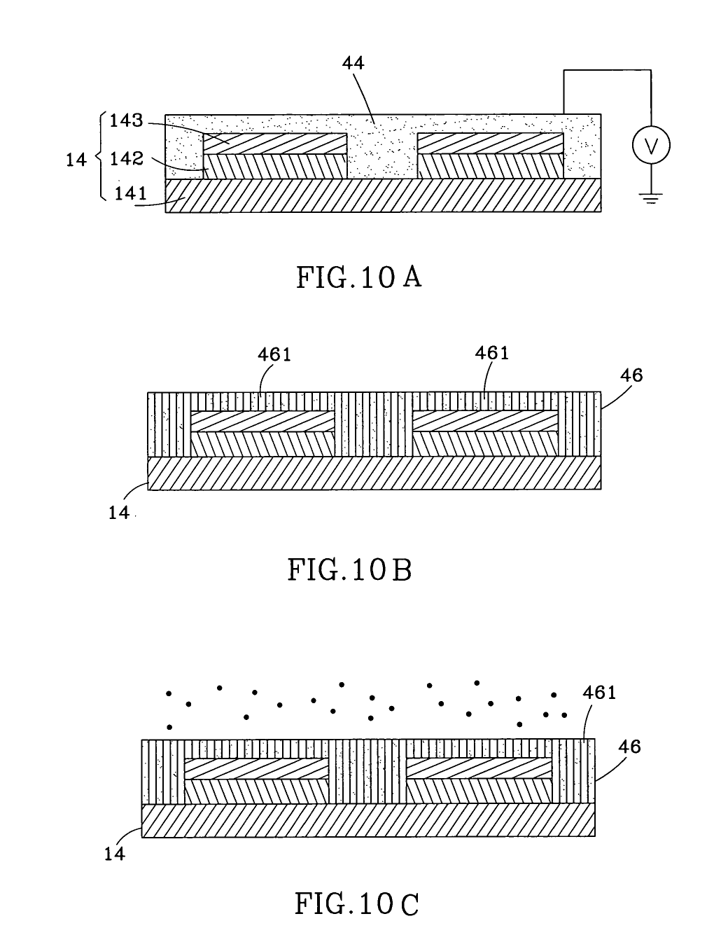

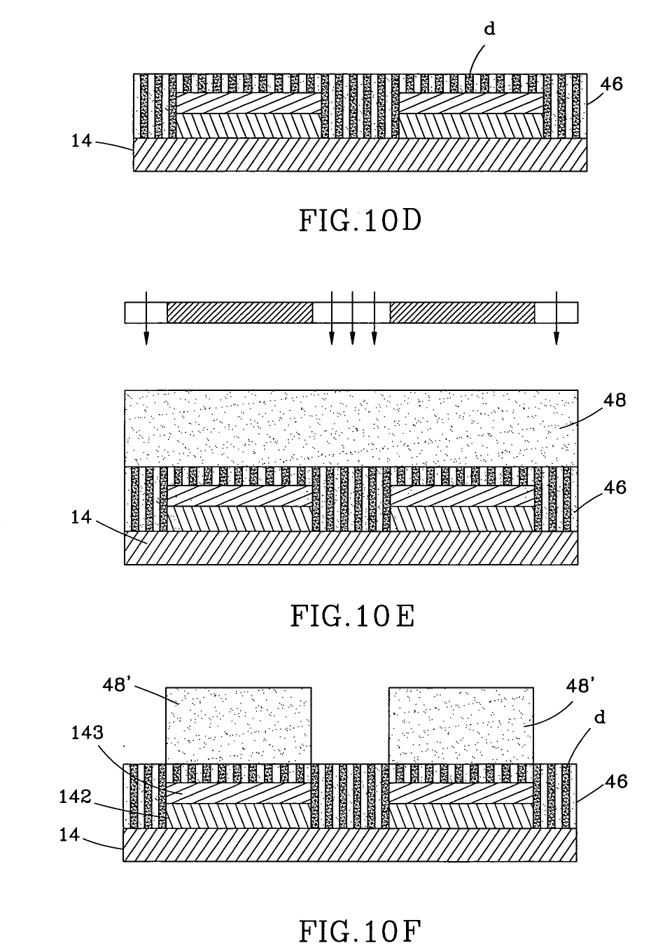

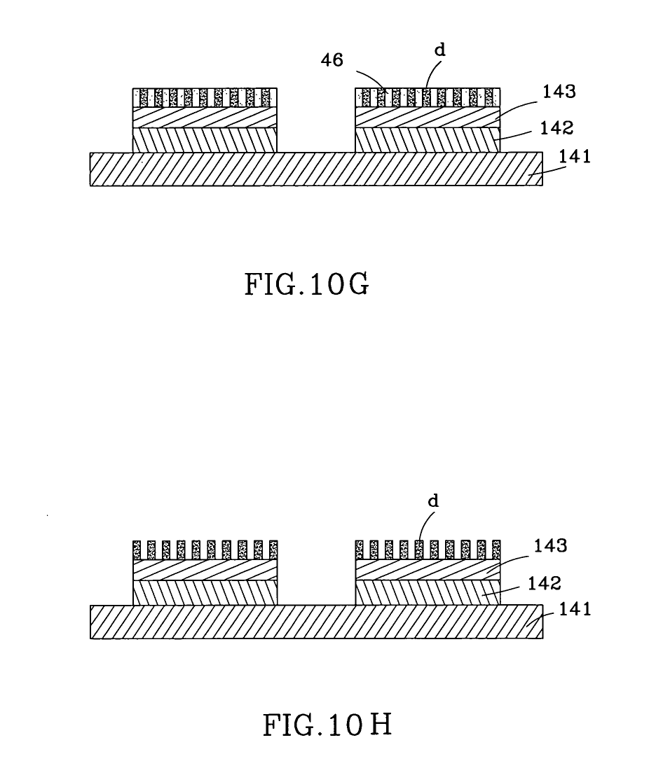

As shown in FIG. 10A, the second electronic member 14 with an aluminum film 44 is placed in an electrolytic bath (not shown) and provided with a voltage to the aluminum film 44 to form an aluminum oxide film 46 with a plurality of nanoscale vias 461, as shown in FIG. 10B. Metal depositions d are formed in the vias 461 respectively by chemical vapor deposition (CVP), or physical vapor deposition (PVD), as shown in FIGS. 10C and 10D. And then, a positive photoresist 48 is coated on the aluminum oxide film 46, and the exposure and development treatments are carried out to have a photoresist pattern 48′ on the aluminum oxide film 46, as shown in FIGS. 10E and 10F. The exposed portions of the aluminum oxide film 46, metal depositions d, second conductive layers 143 and the conductive films 142 are removed by wet-etching treatment, and then the photoresist pattern 48′ is removed too, as shown in FIG. 10G. Finally, the residual aluminum oxide film 46 is removed by wet-etching treatment, so that the second conductive layers 143 have the metal depositions d thereon, which form the nanoscale posts.

The third method of making the nanoscale posts includes the steps hereunder:

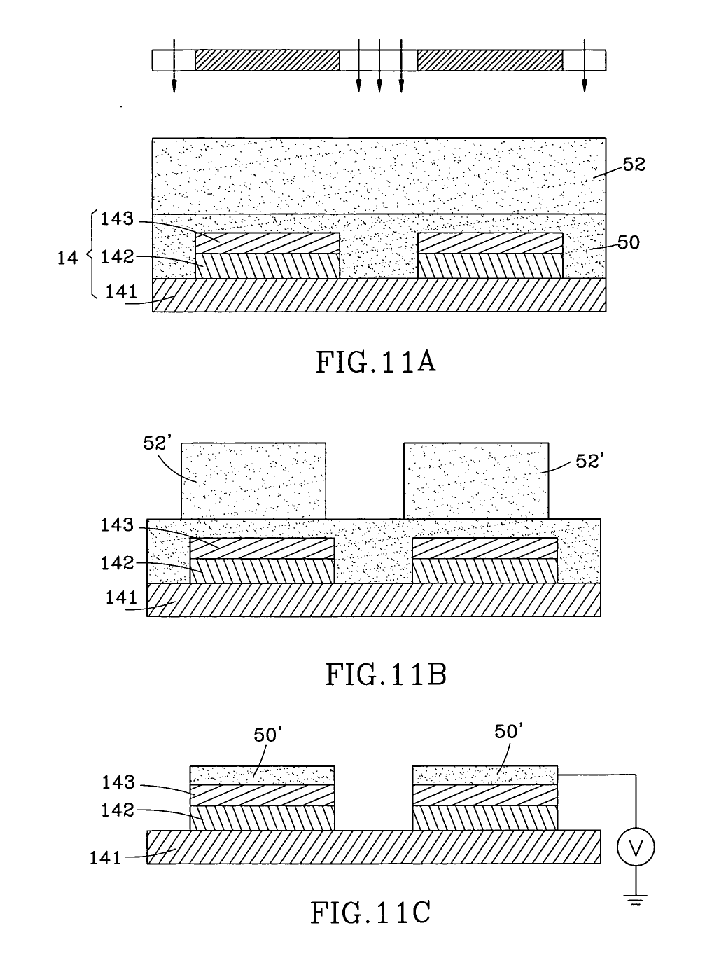

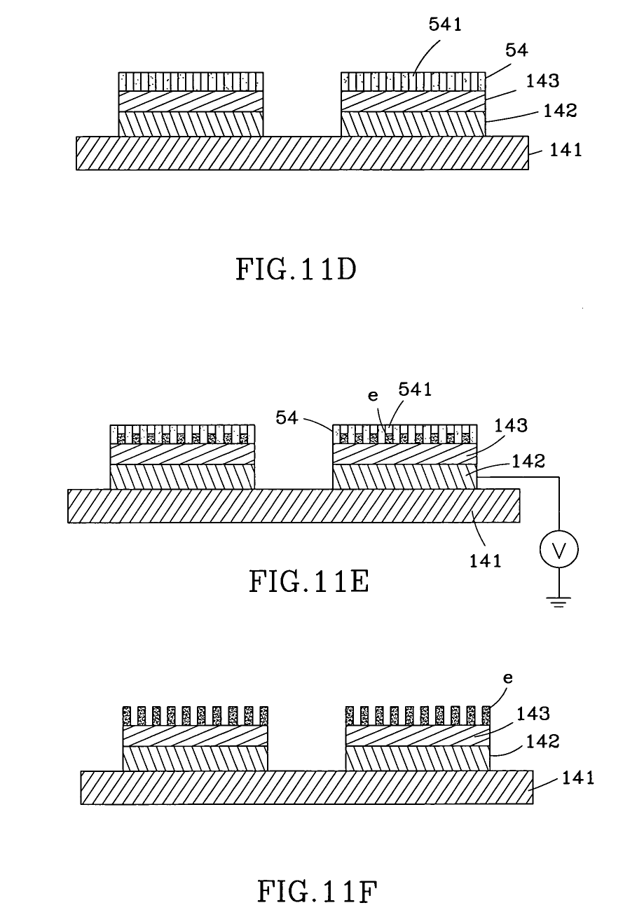

As shown in FIG. 11A, an aluminum film 50 is formed on the second electronic member 14, and then a positive photoresist 52 is coated on the aluminum film 50. After the exposure and development treatments, a photoresist pattern 52′ is left on the aluminum film 50, as shown in FIG. 11B. The exposed portions of the aluminum film 50, the second conductive layers 143 and the conductive films 142 are removed by etching treatment, and then the photoresist pattern 52′ is removed too. The second electronic member 14 has the second conductive layers 143 with the aluminum films 50′ thereon, as shown in FIG. 11C. And then, the second electronic member 14 is placed in an electrolytic bath (not shown) with sulfuric acid, phosphoric acid, or oxalic acid, and a voltage is provided to the aluminum films 50′ to form aluminum oxide films 54 with a plurality of nanoscale vias 541, as shown in FIG. 11D. And then, the second electronic member 14 is placed into an electroforming tank (not shown), and a voltage is provided to the conductive films 142 to deposit metal depositions e in the vias 541 respectively, as shown in FIG. 11E. Finally, the aluminum oxide films 54 is removed by wet-etching treatment to have the metal depositions e on the second conductive layers 143, as shown in FIG. 11F, which form the nanoscale posts.

It has to be mentioned that the microscale or nanoscale posts 20 may be formed on the conductive films 142 directly, as shown in FIG. 12. In other words, the second electronic member 14 may have no second conductive layer 143 for simplifying the manufacturing processes thereof.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A display panel package, comprising:
a first electronic member;
a second electronic member;
an electrically conductive structure for electrically connecting the first electronic member and the second electronic member, wherein the electrically conductive structure comprises:
a plurality of bumps electrically spacedly connected to the first electronic member, and
a plurality of posts electrically connected to the second electronic member and penetrated into the bumps respectively.

2. The display panel package as defined in claim 1, wherein the posts have a hardness greater than that of the bumps.

3. The display panel package as defined in claim 1, wherein the first electronic member has a first conductive layer on which the bumps are formed and pointed to the second electronic member.

4. The display panel package as defined in claim 1, wherein the second electronic member has a substrate and a plurality of conductive films on the substrate, the conductive films are spacedly arranged with respect to each other, and the posts are projected from the conductive films respectively and pointed to the bumps of the first electronic member.

5. The display panel package as defined in claim 3, wherein the second electronic member has a substrate and a plurality of conductive films on the substrate, the conductive films are spacedly arranged with respect to each other, and the posts are projected from the conductive films respectively and pointed to the bumps of the first electronic member.

6. The display panel package as defined in claim 1, wherein the second electronic member has a substrate, a plurality of conductive films on the substrate and a plurality of second conductive layers on the conductive films respectively, the conductive films are spacedly arranged with respect to each other, and the posts are projected from the second conductive layers respectively and pointed to the bumps of the first electronic member.

7. The display panel package as defined in claim 3, wherein the second electronic member has a substrate, a plurality of conductive films on the substrate and a plurality of second conductive layers on the conductive films respectively, the conductive films are spacedly arranged with respect to each other, and the posts are projected from the second conductive layers respectively and pointed to the bumps of the first electronic member.

8. The display panel package as defined in claim 1, further comprising a non-conductive adhesion between the first electronic member and the second electronic member.
